(19) United States
(12) Patent Application Publication
(10) Pub. No.: US 2025/0089307 A1
(43) Pub. Date: Mar. 13, 2025

(54) SEMICONDUCTOR DEVICE

(71) Applicant: Mitsubishi Electric Corporation, Tokyo (JP)

(72) Inventors: Kazuya KONISHI, Tokyo (JP); Kohei SAKO, Tokyo (JP); Naoyuki KAWABATA, Tokyo (JP); Yu NAKAMURA, Tokyo (JP); Kakeru OTSUKA, Tokyo (JP)

(73) Assignee: Mitsubishi Electric Corporation, Tokyo (JP)

(21) Appl. No.: 18/770,313

(22) Filed: Jul. 11, 2024

(30) Foreign Application Priority Data
Sep. 13, 2023 (JP) 2023-148452

(51) Int. Cl. H01L 29/06; H01L 29/739

(52) U.S. Cl. CPC H10D 62/102; H10D 12/481

(57) ABSTRACT

An extension part of a lower electrode extending to an outer side of an upper electrode in the lower electrode further extends to an upper surface of a semiconductor substrate to cover an end portion of the upper electrode in an outer surrounding part of a trench located, in an outer surrounding region in an extension direction, and a width of the trench is smallest in a trench end portion.

### BACKGROUND OF THE INVENTION

### Field of the Invention

The present disclosure relates to a semiconductor device.

### Description of the Background Art

Japanese Patent Application Laid-Open No. 2021-128948 discloses a semiconductor device including a MOSFET having a split gate structure in which an electrode in a trench is divided to upper and lower sides. The invention described in Japanese Patent Application Laid-Open No. 2021-128948 increases a width of the trench in an outer surrounding part of the semiconductor device, thereby improving withstand voltage of a trench end portion located in the outer surrounding part. It also describes that the invention can be applied even in a case where a semiconductor switching element is an IGBT other than the MOSFET.

The semiconductor device described in Japanese Patent Application Laid-Open No. 2021-128948 has insufficient consideration for a movement of a carrier. Considered as an example is increase of a hole density in the trench end portion in a turn-off switching operation. Specifically, holes flow in the trench end portion at a high density in the turn-off switching operation, and the hole density increases in the trench end portion. Then, space charge increases in accordance with the increase of the hole density, thus an electrical field increases, and avalanche occurs. Particularly, this phenomenon significantly occurs in an insulated gate bipolar transistor (IGBT) in a bipolar device. When the invention described in Japanese Patent Application Laid-Open No. 2021-128948 is applied to the IGBT, the width of the trench increases in the trench end portion located in the outer surrounding part, thus a region between the trenches narrows, and the hole density easily increases. Thus, the electrical field increases in accordance with the increase of the hole density, and avalanche withstand voltage decreases.

### SUMMARY

An object of the present disclosure is to provide a semiconductor device reducing a hole density in a trench end portion, thereby suppressing increase of an electrical field and improving avalanche withstand voltage.

A semiconductor device including an active region and an outer surrounding region, wherein a semiconductor switching element is provided in the active region, and the outer surrounding region is located in a region where a gate electrode is provided on an outer side of the active region.

The semiconductor switching element includes a first conductivity type drift layer, a second conductivity type base layer, a first conductivity type source layer, a second conductivity type collector layer, an emitter electrode, and a collector electrode.

The second conductivity type base layer is provided on a side of an upper surface of the first conductivity type drift layer, the first conductivity type source layer is provided on a side of an upper surface of the second conductivity type base layer, the second conductivity collector layer is provided on a side of a lower surface of the first conductivity type drift layer, the emitter electrode is electrically connected to the first conductivity type source layer, and the collector electrode is electrically connected to the second conductivity type collector layer.

A range from an upper surface of the first conductivity type source layer to a lower surface of the second conductivity type collector layer is defined as a semiconductor substrate.

The semiconductor device further includes a plurality of trenches and an interlayer insulating film.

The plurality of trenches pass through the semiconductor substrate from an upper surface of the semiconductor substrate to reach the first conductivity type drift layer in a depth direction, and extend from the active region to the outer surrounding region, and the interlayer insulating film covers each of the plurality of trenches.

Each of the plurality of trenches has a two-stage structure that a lower electrode, a boundary insulating film, and an upper electrode are stacked in sequence via an insulating film inside each of the plurality of trenches.

The lower electrode is electrically connected to the emitter electrode, and the upper electrode is electrically connected to the gate electrode.

An extension part of the lower electrode extending to an outer side of the upper electrode further extends to the upper surface of the semiconductor substrate to cover an end portion of the upper electrode, in an outer surrounding part of each of the plurality of trenches located in the outer surrounding region in an extension direction.

A width of each of the plurality of trenches is smallest in a trench end portion.

According to the present disclosure, a hole density in the trench end portion is reduced, thus increase of an electrical field is suppressed, and avalanche withstand voltage can be improved.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a whole plan view of a semiconductor device according to an embodiment 1.

FIG. 2 is a cross-sectional view of the semiconductor device according to the embodiment 1 along an A-A line in FIG. 1.

FIG. 3 is a cross-sectional view of the semiconductor device according to the embodiment 1 along a B-B line in FIG. 1.

FIG. 4 is an enlarged plan view of an area C in FIG. 1 of the semiconductor device according to the embodiment 1.

FIG. 5 is an enlarged plan view of an outer surrounding part of a trench of the semiconductor device according to the embodiment 1.

FIG. 6 is an enlarged plan view of an outer surrounding part of a trench of a semiconductor device according to an embodiment 2.

FIG. 7 is an enlarged plan view of the outer surrounding part of the trench of the semiconductor device according to the embodiment 2.

FIG. 8 is an enlarged plan view of an outer surrounding part of a trench of a semiconductor device according to an embodiment 3.

FIG. 9 is an enlarged plan view of the outer surrounding part of the trench of the semiconductor device according to the embodiment 3.

FIG. 10 is an enlarged plan view of the outer surrounding part of the trench of the semiconductor device according to the embodiment 3.

FIG. 11 is an enlarged plan view of an outer surrounding part of a trench of a semiconductor device according to an embodiment 4.

### DESCRIPTION OF THE PREFERRED EMBODIMENTS

### Introduction

In the description hereinafter, an n type and a p type indicate a conductivity type of a semiconductor, and a first conductivity type is an n type and a second conductivity type is a p type in the present disclosure, however, the first conductivity type may be a p type, and the second conductivity type may be an n type. An n⁻ type indicates that an impurity concentration thereof is lower than that of the n type, and an n⁺ type indicates that an impurity concentration thereof is higher than that of the n type. In the similar manner, a p⁻ type indicates that an impurity concentration thereof is lower than that of the p type, and a p⁺ type indicates that an impurity concentration thereof is higher than that of the p type.

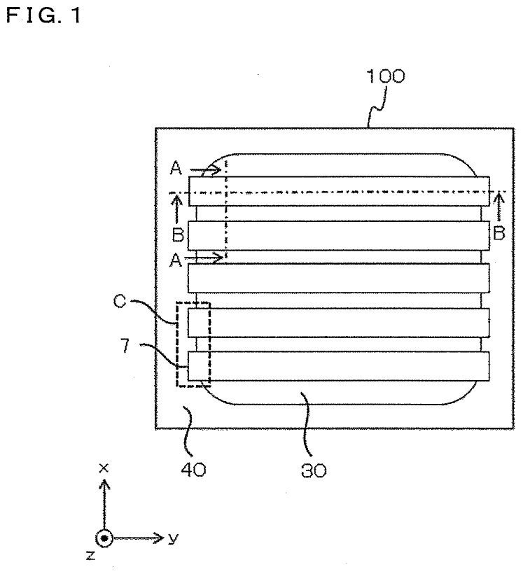

In the description hereinafter, for convenience of description, a width direction of a semiconductor device 100 is an x direction, a length direction of the semiconductor device 100 intersecting with the x direction is a y direction, a normal direction with respect to a thickness direction or a depth direction of the semiconductor device 100, that is an xy plane is a z direction as illustrated in FIG. 1 to FIG. 11.

Since the drawings are schematically illustrated, a mutual relationship of sizes and positions of images respectively illustrated in the different drawings is not necessarily illustrated accurately, but may be appropriately changed. In the description hereinafter, the same reference numerals will be assigned to the similar constituent elements in the drawings, and the constituent elements having the same reference numeral have the similar name and function. Accordingly, the detailed description on them may be omitted in some cases.

### Embodiment 1

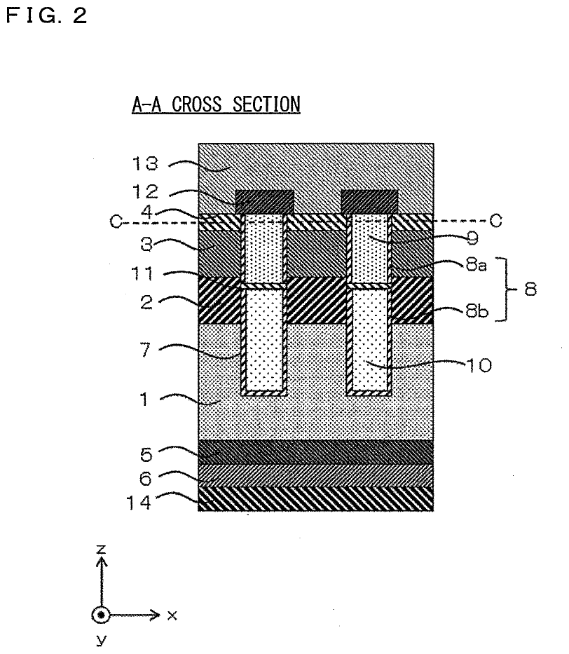

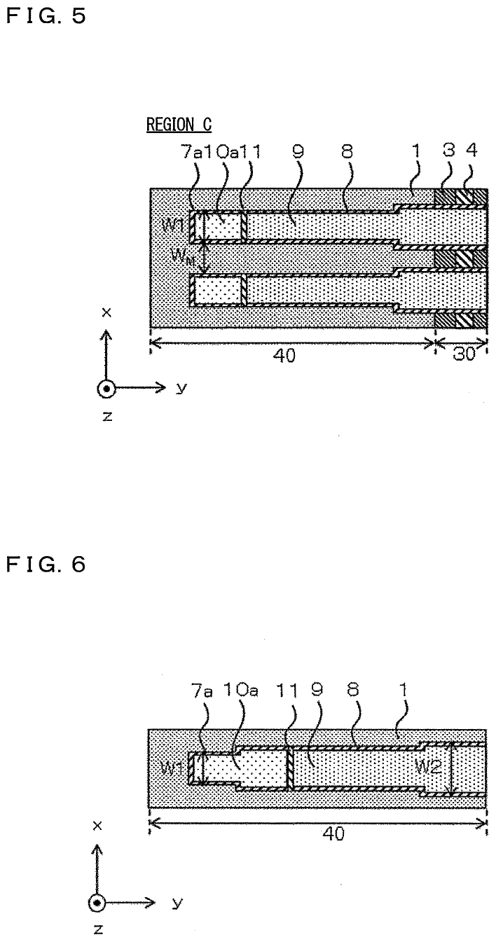

An embodiment 1 is described hereinafter using the drawings. FIG. 1 is a plan view schematically illustrating an upper configuration of a whole semiconductor device 100 according to the embodiment 1. As illustrated in FIG. 1, the semiconductor device 100 includes an active region 30 where a semiconductor switching element is provided and an outer surrounding region 40 around the active region 30. Furthermore, a trench 7 is provided to extend from the active region 30 to the outer surrounding region 40 in a Y direction. The Y direction is an extension direction of the trench 7. The plurality of trenches 7 are provided adjacent to each other in an X direction perpendicular to the extension direction of the trench 7. The number of the trenches 7 is five in FIG. 5, but is not limited thereto. Described in the present embodiment is an example of a semiconductor device having a split gate trench structure using an insulated gate bipolar transistor (abbreviated as IGBT hereinafter) as the semiconductor switching element. A detailed structure of the semiconductor device 100 according to the present embodiment is described hereinafter based on FIG. 2 to FIG. 5.

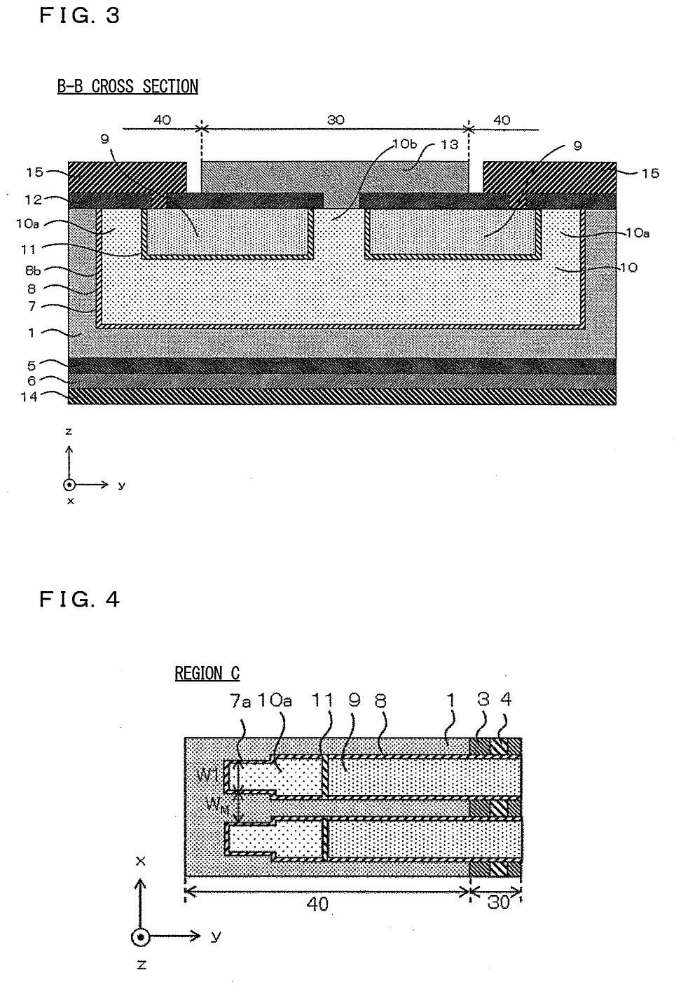

FIG. 2 is a cross-sectional view of the active region 30 of the semiconductor device 100 according to the embodiment 1 in a direction perpendicular to the extension direction of the trench 7. FIG. 2 illustrates a cross section along a dash-dotted line A-A in FIG. 1. FIG. 3 is a cross-sectional view in a direction parallel to the extension direction of the trench 7 according to the embodiment 1. FIG. 3 illustrates a cross section along a dash-dotted line B-B in FIG. 1. FIG. 4 is a plan view of an outer surrounding part of the trench 7 of the semiconductor device 100 according to the embodiment 1. FIG. 4 illustrates an enlarged view in a region C in FIG. 1 and a plan view along a dotted line C in FIG. 2. FIG. 5 is a plan view illustrating a modification example of the trench 7 in FIG. 4.

A cross-sectional configuration of the semiconductor device 100 is described firstly using FIG. 2 and FIG. 3. As illustrated in FIG. 2, the semiconductor device 100 includes the semiconductor switching element in the active region 30. The semiconductor switching element includes an n⁻-type drift layer 1, an n-type carrier accumulation layer 2, a p-type base layer 3, an n⁺-type source layer 4, an n-type buffer layer 5, a p-type collector layer 6, the trench 7, an upper insulating film 8a, a lower insulating film 8b, an upper electrode 9, a lower electrode 10, a boundary insulating film 11, an interlayer insulating film 12, an emitter electrode 13, and a collector electrode 14.

As illustrated in FIG. 3, a gate electrode 15 is provided in the outer surrounding region 40.

A first main surface of a semiconductor substrate in the active region 30 corresponds to a surface (upper surface) of n⁺-type source layer 4 and a p+-type contact layer not shown in the drawings. The first main surface is an upper surface of the semiconductor substrate. A second main surface of the semiconductor substrate corresponds to a surface (lower surface) of the p-type collector layer 6. The second main surface is a surface on a side opposite to the first main surface and is a lower upper surface of the semiconductor substrate. In FIG. 2, the semiconductor substrate corresponds to a range from the upper surfaces of n⁺-type source layer 4 and the p⁺-type contact layer to the lower surface of the p-type collector layer 6.

The n⁻-type drift layer 1 is made up of the semiconductor substrate. The n⁻-type drift layer 1 is provided between the first main surface and the second main surface of the semiconductor substrate. The n⁻-type drift layer 1 is a semiconductor layer containing arsenic or phosphorus, for example, as an n-type impurity, and a concentration of the n-type impurity is 1.0E+12/cm³ to 1.0E+15/cm³.

The n-type carrier accumulation layer 2 is provided on a side of the first main surface of the semiconductor substrate with respect to the n⁻-type drift layer 1. The n-type carrier accumulation layer 2 is a semiconductor layer containing arsenic or phosphorus, for example, as an n-type impurity, and a concentration of the n-type impurity is preferably 1.0E+13/cm³ to 1.0E+17/cm³. The n-type carrier accumulation layer 2 is provided, thus power conduction loss at a time of flowing current can be reduced. The semiconductor device 100 may have a configuration that the n-type carrier accumulation layer 2 is not provided, but the n⁻-type drift layer 1 is provided also in the region of the n-type carrier accumulation layer 2, and the n-type carrier accumulation layer 2 and the n⁻-type drift layer 1 may be collectively defined as the drift layer.

The p-type base layer 3 is provided on a side of the first main surface of the semiconductor substrate with respect to the n-type carrier accumulation layer 2. The p-type base layer 3 is a semiconductor layer containing boron or aluminum, for example, as a p-type impurity, and a concentration of the p-type impurity is preferably 1.0E+12/cm³ to 1.0E+19/cm³. The p-type base layer 3 has contact with the upper insulating film 8 of the trench 7. When gate drive voltage is applied to the upper electrode 9, a channel is formed in the p-type base layer 3.

The n⁺-type source layer 4 is provided on the side of the first main surface of the semiconductor substrate with respect to the p-type base layer 3. The n⁺-type source layer 4 is selectively provided on an upper side of the p-type base layer 3 as a surface layer of the semiconductor substrate. The n⁺-type source layer 4 is a semiconductor layer containing arsenic or phosphorus, for example, as an n-type impurity, and a concentration of the n-type impurity is preferably 1.0E+17/cm³ to 1.0E+20/cm³. The n⁺-type source layer 4 has contact with the upper insulating film 8a of the trench 7. The n⁺-type source layer 4 is referred to as the n⁺-type emitter layer in some cases.

Although not shown in the drawings, the p+-type contact layer is provided on the side of the first main surface of the semiconductor substrate with respect to the p-type base layer 3. The p⁺-type contact layer is selectively provided on the upper side of the p-type base layer 3 as the surface layer of the semiconductor substrate. The p⁺-type contact layer is provided in a region where the n⁺-type source layer 4 is not provided along the extension direction of the trench 7 on the upper side of the p-type base layer 3. The p⁺-type contact layer is a semiconductor layer containing boron or aluminum, for example, as a p-type impurity, and a concentration of the p-type impurity is preferably 1.0E+15/cm³ to 1.0E+20/cm³. The p⁺-type contact layer is a region having a higher p-type impurity concentration than the p-type base layer 3. When the p⁺-type contact layer and the p-type base layer 3 need to be distinguished, they may be individually referred, and the p⁺-type contact layer and the p-type base layer 3 may be collectively defined as the p-type base layer 3.

The n-type buffer layer 5 is provided on a side of the second main surface of the semiconductor substrate with respect to the n⁻-type drift layer 1. The n-type buffer layer 5 is a semiconductor layer containing at least one of phosphorus and proton, for example, as an n-type impurity, and a concentration of the n-type impurity is preferably 1.0E+12/cm³ to 1.0E+18/cm³. The n-type buffer layer 5 has a higher n-type impurity concentration than the n-type drift layer 1. The n-type buffer layer 5 reduces a depletion layer extending from the p-type base layer 3 to the side of the second main surface to cause punch-through when the semiconductor device 100 is in an OFF state. The n-type buffer layer 5 and the n⁻-type drift layer 1 may be collectively defined as one n⁻-type drift layer 1. Furthermore, the n-type carrier accumulation layer 2, the n-type buffer layer 5, and the n⁻-type drift layer 1 may be collectively defined as one n⁻-type drift layer 1. The n-type buffer layer 5 needs not be necessarily provided, however, the n⁻-type drift layer 1 may be provided in the region of the n-type buffer layer 5.

The p-type collector layer 6 is provided on the side of the second main surface of the semiconductor substrate with respect to the n-type buffer layer 5. The p-type collector layer 6 is a semiconductor layer containing boron or aluminum, for example, as a p-type impurity, and a concentration of the p-type impurity is preferably 1.0E+16/cm³ to 1.0E+20/cm³.

The trench 7 is provided on the first main surface of the semiconductor substrate, that is to say, the upper surface of the semiconductor substrate.

The trench 7 passes through the n⁺-type source layer 4 and the p-type base layer 3 from the first main surface of the semiconductor substrate to reach the n⁻-type drift layer 1.

An inner wall surface of the trench 7 is covered by an insulating film 8. The insulating film 8 may be made up of a single film, but is made up of the upper insulating film 8a covering an upper portion of the trench 7 and the lower insulating film 8b covering a lower portion thereof in the present embodiment. The upper insulating film 8a covers a side surface of the upper portion of the trench 7, and the lower insulating film 8b covers a side surface of the lower portion of the trench 7 from a bottom part thereof. The upper insulating film 8a and the lower insulating film 8b are oxide films, for example. A thickness of the lower insulating film 8b may be larger than that of the upper insulating film 8a. According to such a configuration, breakdown of the insulating film caused by an electrical field concentration can be suppressed in a trench end portion 7a described hereinafter.

Furthermore, the trench 7 has a two-stage structure with two electrodes of the upper electrode 9 and the lower electrode 10, that is a split gate structure therein. The upper electrode 9 is provided in the trench 7 via the upper insulating film 8a, and the lower electrode 10 is provided on a side of a second main surface of the upper electrode 9 via the lower insulating film 8b. The boundary insulating film 11 insulates the upper electrode 9 and the lower electrode 10. That is to say, the lower electrode, the boundary insulating film, and the upper electrode are stacked in sequence via the insulating film inside the trench 7 to constitute the two-stage structure. Herein, the lower electrode 10 faces the n⁻-type drift layer 1 via the lower insulating film 8b. A bottom part of the upper electrode 9 is located closer to the side of the second main surface in relation to the p-type base layer 3.

The upper electrode 9 and the lower electrode 10 are formed by depositing polysilicon doped with an n-type or p-type impurity. A concentration of the impurity of polysilicon is 1.0E+17/cm³ to 1.0E+22/cm³. An impurity concentration of the lower electrode 10 is higher than that of the upper electrode 9, and is 1.0E+19/cm³ to 1.0E+22/cm³, for example. The impurity concentration thereof is preferably 1.0E+20/cm³ to 1.0E+22/cm³.

As illustrated in FIG. 3, the upper electrode 9 is electrically connected to the gate electrode 15 in the outer surrounding region 40, and the lower electrode 10 is electrically connected to the emitter electrode 13 in the active region 30. Furthermore, the lower electrode 10 is provided to extend to an outer side of the upper electrode 9 in outer surrounding part of the trench 7 located in the outer surrounding region 40 in the extension direction.

A part of the lower electrode 10 provided to extend to an outer side of the upper electrode 9 is referred to as an extension part 10a of the lower electrode 10. Then, the extension part 10a is further provided to extend to the first main surface of the semiconductor substrate to cover an end portion of the upper electrode 9. The boundary insulating film 11 also insulates the extension part 10a from the upper electrode 9. A part of the lower electrode 10 for electrically connecting the lower electrode 10 to the emitter electrode 13 is referred to as a lifting region part 10b. The lifting region part 10b is further provided to extend to the first main surface of the semiconductor substrate to pass through the upper electrode 9. The boundary insulating film 11 also insulates the lifting region part 10b from the upper electrode 9.

As illustrated in FIG. 3, the interlayer insulating film 12 is provided on the upper electrode 9 and the lower electrode 10 of the trench 7.

A barrier metal not shown in the drawings is formed on a region where the interlayer insulating film 12 is not provided in the first main surface of the semiconductor substrate and on the interlayer insulating film 12. The barrier metal is formed of a conductor containing titanium, for example. The conductor containing titanium is titanium nitride and TiSi, for example. TiSi is alloy of titanium and silicon (Si). The barrier metal has ohmic contact with the n⁺-type source layer 4, the p⁺-type contact layer, and the lower electrode 10. The barrier metal is electrically connected to the n⁺-type source layer 4, the p⁺-type contact layer, and the lower electrode 10.

The emitter electrode 13 is provided on the barrier metal in the active region 30. The emitter electrode 13 is formed of aluminum silicon alloy (Al—Si series alloy), for example. The emitter electrode 13 is electrically connected to the n⁺-type source layer 4, the p⁺-type contact layer, and the lower electrode 10 via the barrier metal. The emitter electrode 13 may be made up of a plurality of metal films including an aluminum alloy film and the other metal film. For example, the emitter electrode 13 may be made up of an aluminum alloy film and a plating film. The plating film is formed of non-electrolytic plating or electrolytic plating, for example. The plating film is a nickel (Ni) film, for example. A tungsten film may be formed in a minute region between the interlayer insulating films 12 adjacent to each other. The emitter electrode 13 is formed on the tungsten film. The tungsten film has more favorable embedding properties than the plating film, thus the favorable emitter electrode 13 is formed.

The barrier metal and the emitter electrode 13 may be collectively defined as one emitter electrode 13. The barrier metal needs not be necessarily provided.

When the barrier metal is not provided, the emitter electrode 13 is provided on the n⁺-type source layer 4, the p⁺-type contact layer, and the lower electrode 10, and has ohmic contact with them.

The barrier metal may be provided only on an n-type semiconductor layer such as the n⁺-type source layer 4. The interlayer insulating film 12 may be provided on a part of the lower electrode 10.

In such a case, the emitter electrode 13 is electrically connected to the lower electrode 10 in some region on the lower electrode 10.

As illustrated in FIG. 3, the gate electrode 15 is provided on the n⁻-type drift layer 1 and the upper electrode 9 in the outer surrounding region 40, and has ohmic contact with them. The interlayer insulating film 12 may be provided on a part of the lower electrode 9. In such a case, the gate electrode 15 is electrically connected to the upper electrode 9 in some region on the upper electrode 9.

The collector electrode 14 is provided on the side of the second main surface of the semiconductor substrate with respect to the p-type collector layer 6. The collector electrode 14 is formed of aluminum alloy in the manner similar to the emitter electrode 13, for example. The collector electrode 14 has ohmic-contact with the p-type collector layer 6, and is electrically connected to the p-type collector layer 6. The collector electrode 14 may be made up of aluminum alloy film and a plating film. The collector electrode 14 may have a configuration different from the emitter electrode 13.

As described above, the semiconductor device 100 including the IGBT is formed. Subsequently, described in detail is a structure of the outer surrounding part of the trench 7 in the extension direction in the structure of the trench 7 described above with reference to FIG. 4.

As illustrated in FIG. 4, a region in the trench 7 corresponding to the extension part 10a of the lower electrode 10 is a trench end portion 7a. A trench width is smallest in the trench end portion 7a. Herein, a width of the trench end portion 7a is a first width W1, and the trench width is the smallest W1 in the trench end portion 7a.

According to the configuration described above, avalanche withstand voltage of the semiconductor device 100 can be improved. This reason is described hereinafter.

In an ON state in the IGBT, a large amount of electrons and holes flow toward the n⁻-type drift layer 1. Next, in a turn-off switching operation, flowing of the electrons and the holes into the n−-type drift layer 1 is stopped. Herein, the holes flowing into the n⁻-type drift layer 1 flow from the outer surrounding region 40 which has no discharge path toward the emitter electrode 13 from which the holes are discharged. That is to say, the holes also flow into the trench end portion 7a at a high density, and a hole density of the trench end portion 7a increases. The flowing of the electrons is stopped. A space charge density thereby increases in the trench end portion 7a, and an electrical field strength increases, thus avalanche occurs.

As described above, applied is the configuration that the trench width is the smallest W1 at the trench end portion 7a, thus a mesa width W_{M} of a region between the trenches can be increased at the trench end portion 7a, thus the discharge path of the holes can be enlarged, and the hole density can be reduced. Accordingly, the space charge density can be reduced, increase of the electrical field strength is suppressed, and avalanche withstand voltage can be improved.

The lower electrode 10 is electrically connected to the emitter electrode 13, thus has lower potential than the upper electrode 9. Thus, the holes is pulled to not only a sidewall of a region corresponding to the upper electrode 9 in the trench 7 but also a sidewall of a region corresponding to the lower electrode 10 in the turn-off switching operation. As described above, applied is the configuration of locating the extension part 10a of the lower electrode 10 in a tip end portion in the trench 7, thus the holes can also be pulled to the sidewall of the trench end portion 7a, and a p-type reverse layer having low resistance can be formed in the n⁻-type drift layer 1. That is to say, the holes can pass through the p-type reverse layer having the low resistance in the trench end portion 7a, thus discharge of the holes is promoted.

Next, a modification example of the embodiment 1 is described using FIG. 5.

As illustrated in FIG. 5, a region where the trench width is smallest may be a region corresponding to a part of the upper electrode 9 in addition to a region corresponding to the extension part 10a in the trench 7. Herein, the region corresponding to the part of the upper electrode 9 is a region corresponding to the upper electrode 9 in the outer surrounding region 40. According to such a configuration, the region where the trench width is the smallest W1 in the trench 7 is enlarged. The region where the mesa width W_{M} is large is enlarged, thus the hole density can be further reduced, and the avalanche withstand voltage can be improved.

As described above, in the semiconductor device 100 according to the present embodiment, the mesa width is changed by changing the trench width, and the mesa width of the trench end portion 7a is made to be largest. Accordingly, the hole density can be reduced in the trench end portion 7a, and improvement of the avalanche withstand voltage can be achieved in the semiconductor device 100 including the IGBT having the split gate structure.

Furthermore, the discharge path of the holes can be enlarged in the semiconductor device 100 according to the present embodiment, thus the holes can be discharged and turn-off power loss can be reduced. The turn-off power loss is reduced, thus switching loss can be reduced in the semiconductor device 100 including the IGBT having the split gate structure.

A method of manufacturing the semiconductor device 100 according to the present embodiment is basically similar to that of the semiconductor device 100 including a conventional IGBT having a split gate trench structure. However, used is an etching mask in which the trench width in at least the trench end portion 7a is the smallest W1 in the trench 7 in an etching process of forming the trench 7.

The method of manufacturing the semiconductor device 100 is described in detail. The method of manufacturing the semiconductor device 100 includes a step of preparing the semiconductor substrate, a process of forming the side of the first main surface of the semiconductor substrate, and a process of forming the side of the second main surface of the semiconductor substrate.

The process of preparing the semiconductor substrate is described firstly. In the present embodiment, an n-type wafer including an n-type impurity is prepared as the semiconductor substrate. The semiconductor substrate may be a so-called floating zone (FZ) wafer manufactured by an FZ method or a so-called magnetic field applied CZochralki (MCZ) wafer manufactured by an MCZ method. The semiconductor substrate may be a wafer manufactured by a sublimation method or a chemical vapor deposition (CVD). In the process, the whole semiconductor substrate corresponds to an n⁻-type drift layer 1. A concentration of an n-type impurity is appropriately selected by a withstand voltage specification of the semiconductor device 100. For example, when the withstand voltage specification of the semiconductor device 100 is 1200 V, the concentration of the n-type impurity is adjusted so that specific resistance of the n⁻-type drift layer 1 is appropriately 40 to 120 Ω·cm. Described in the present embodiment is the process of preparing the n-type wafer in which the whole semiconductor substrate is the n⁻-type drift layer 1, however, the process of preparing the semiconductor substrate is not limited thereto. For example, the semiconductor substrate including the n⁻-type drift layer 1 may be prepared by a process of ion-implanting an n-type impurity from the first main surface or the second main surface of the semiconductor substrate and a process of diffusing the n-type impurity by a heat treatment.

Described next is the process of forming the side of the first main surface of the semiconductor substrate. Firstly, an n-type impurity for forming the n-type carrier accumulation layer 2 is ion-implanted into a surface layer of the n⁻-type drift layer 1 from the side of the first main surface of the semiconductor substrate. The n-type impurity is phosphorus, for example.

Next, a p-type impurity for forming the p-type base layer 3 is ion-implanted from the side of the first main surface of the semiconductor substrate. The p-type impurity is boron, for example. After the ion implantation, a heat treatment is performed to diffuse the n-type impurity and the p-type impurity, and the n-type carrier accumulation layer 2 and the p-type base layer 3 are formed.

After the ion implantation described above, a mask having an opening in a predetermined region is formed on the first main surface of the semiconductor substrate. The n-type impurity and the p-type impurity are implanted in a region corresponding to the opening of the mask. The mask is formed by a process of applying a resist on the first main surface of the semiconductor substrate and a process of forming an opening in a predetermined region of the resist by a photolithography technique. Such a process of forming the mask having the opening in the predetermined region is referred to as mask processing. The n-type impurity and the p-type impurity are implanted in a predetermined region by the mask processing. As a result, the n-type carrier accumulation layer 2 and the p-type base layer 3 are selectively provided in a plane of the first main surface of the semiconductor substrate.

Next, an n-type impurity for forming the n⁺-type source layer 4 is ion-implanted from the side of the first main surface of the semiconductor substrate to the surface layer of the p-type base layer 3. At this time, the n-type impurity is implanted by the mask processing, and the n⁺-type source layer 4 is selectively formed in the surface layer of the p-type base layer 3. The n-type impurity is arsenic or phosphorus, for example.

Next, a p-type impurity for forming the p⁺-type contact layer is ion-implanted from the side of the first main surface of the semiconductor substrate to the surface layer of the p-type base layer 3. At this time, the p-type impurity is implanted by the mask processing, and each p⁺-type contact layer is selectively formed in the surface layer of the p-type base layer 3. The p-type impurity is boron or aluminum, for example.

Formed next is the trench 7 passing through the n⁺-type source layer 4 and the p-type base layer 3 from the first main surface of the semiconductor substrate to reach the n⁻-type drift layer 1. In the active region 30, the trench 7 passing through the n+-type source layer 4 includes a sidewall constituting a part of the n+-type source layer 4.

An oxide film is deposited on the first main surface of the semiconductor substrate to form the trench 7. The oxide film is a thin film such as SiO₂, for example. Next, an opening is formed in the oxide film in a part where the trench 7 is formed to form mask having the opening. Formed in the mask formation is the mask having the opening in which the trench width in the trench end portion 7a is the smallest width W1 in the trench 7. Finally, the semiconductor substrate is etched via the mask to form the trench 7.

Next, the semiconductor substrate is heated in an atmosphere including oxygen to form the lower insulating film 8b on an inner wall of the trench 7 and the first main surface of the semiconductor substrate. The lower insulating film 8b formed on the first main surface of the semiconductor substrate is removed in a subsequent process.

Next, the lower electrode 10 is formed inside the trench 7 in which the lower insulating film 8b is formed on the inner wall thereof. Polysilicon doped with an n-type or p-type impurity is deposited inside the trench 7 by a chemical vapor deposition (CVD), for example, to form the lower electrode 10. As a result, the lower electrode 10 is formed inside the trench 7 via the lower insulating film 8b.

Next, the mask in which the trench 7 to be filled with the upper electrode 9 is opened is formed by the mask processing to etch the lower electrode 10 in the trench 7. Subsequently, a part of the lower insulating film 8b in the trench 7 in which the upper insulating film 8a is formed is removed.

Next, the semiconductor substrate is heated in an atmosphere including oxygen to form the upper insulating film 8a on the inner wall of the trench 7 and the first main surface of the semiconductor substrate. The boundary insulating film 11 is formed on the main surface of the lower electrode 10. The upper insulating film 8a formed on the first main surface of the semiconductor substrate is removed in a subsequent process.

Next, the upper electrode 9 is formed inside the trench 7 in which the upper insulating film 8a is formed on the inner wall thereof. Polysilicon doped with an n-type or p-type impurity is deposited inside the trench 7 by a chemical vapor deposition (CVD), for example, to form the upper electrode 9. As a result, the upper electrode 9 is formed inside the trench 7 via the upper insulating film 8a.

Next, the interlayer insulating film 12 is formed on the trench 7. The interlayer insulating film 12 is deposited by the mask processing, and the oxide film formed on the first main surface of the semiconductor substrate is removed.

The interlayer insulating film 12 contains SiO2 as an oxide film, for example.

Then, a contact hole is formed in the interlayer insulating film 12. The contact hole is formed on the n⁺-type source layer 4 and the p⁺-type contact layer.

Next, the barrier metal is formed on the first main surface of the semiconductor substrate and the interlayer insulating film 12. The barrier metal is formed by a physical vapor deposition (PDV) or CVD.

Next, the emitter electrode 13 is formed on the barrier metal. The emitter electrode 13 is formed by a PVD method such as sputtering or deposition. The emitter electrode 13 contains aluminum silicon alloy (Al—Si series alloy), for example. Furthermore, the second emitter electrode 13 may be formed on the emitter electrode 13 by a non-electrolytic plating method or an electrolytic plating method, for example. The second emitter electrode 13 contains nickel or nickel alloy, for example. The second emitter electrode 13 has a laminated structure including two or more types of metal layer. The laminated structure is made up of an Ni film, a Pd film, and an Au film, and is formed by a plating method, for example.

The plating method enables easy formation of a thick metal film. A heat capacity increases in the emitter electrode 13 having a thick film, thus heat resistance of the emitter electrode 13 is improved. When nickel alloy is further formed by the plating processing on aluminum silicon alloy, the plating processing may be performed after performing processing on the side of the second main surface of the semiconductor substrate.

Described next is the process of forming the side of the second main surface of the semiconductor substrate. The process of reducing the thickness of the semiconductor substrate is described firstly. The second main surface of the semiconductor substrate is ground to reduce the thickness of the semiconductor substrate to a predetermined thickness in accordance with a design of the semiconductor device. The thickness of the semiconductor substrate after grinding is 80 μm to 200 μm, for example.

Described next is a process of forming the n-type buffer layer 5 and the p-type collector layer 6. Firstly, an n-type impurity for forming the n-type buffer layer 5 is ion-implanted into a surface layer of the n⁻-type drift layer 1 from the side of the second main surface of the thinned semiconductor substrate. Phosphorus or proton, for example, may be implanted as the n-type impurity.

For example, both phosphorus and proton may be implanted.

Proton is implanted from the second main surface of the semiconductor substrate to a deep position at relatively low acceleration energy. An implantation depth of proton is controlled relatively easily by changing the acceleration energy. Thus, when proton is ion-implanted several time while changing the acceleration energy, formed is the n-type buffer layer 5 having a larger width in the thickness direction of the semiconductor substrate than the n-type buffer layer 5 containing phosphorus.

Phosphorus has a higher acceleration rate as the n-type impurity than proton. Even in the thinned semiconductor substrate, the n-type buffer layer 5 containing phosphorus reduces occurrence of punch-through due to increase of the depletion layer more reliably. It is more preferable to form the n-type buffer layer 5 containing both proton and phosphorus to further reduce the thickness of the semiconductor substrate. In such a case, proton is implanted in a deeper position from the second main surface of the semiconductor substrate than phosphorus.

Next, a p-type impurity for forming the p-type collector layer 6 is ion-implanted from the side of the second main surface of the semiconductor substrate. Boron, for example, is implanted as the p-type impurity. The second main surface of the semiconductor substrate is irradiated with laser after the ion implantation. The implanted boron is activated by the laser annealing, and the p-type collector layer 6 is formed.

In this laser annealing, phosphorus as the n-type impurity implanted from the second main surface of the semiconductor substrate to a relatively shallow position is also activated at the same time. In the meanwhile, proton is activated at a relatively low annealing temperature of approximately 350° C. to 500° C. Thus, it is preferable that the semiconductor substrate is not heated to a temperature higher than 350° C. to 500° C. in a process other than the process of activating proton after the implantation of proton. Laser annealing heats only an area near the second main surface of the semiconductor substrate to a high temperature. Thus, the laser annealing is effective in activation of the n-type impurity or the p-type impurity after the implantation of proton.

Described next is a process of forming the collector electrode 14. The collector electrode 14 is formed on the second main surface of the semiconductor substrate. The collector electrode 14 may be formed over the whole second main surface of the semiconductor substrate. The collector electrode 14 contains aluminum silicon alloy or titanium, for example. The collector electrode 14 is formed by a PVD method such as sputtering or deposition. The collector electrode 14 may be made up of a plurality of metal layers each containing aluminum silicon alloy, titanium, nickel, or gold. The collector electrode 14 may have a structure that the other metal film is formed by non-electrolytic plating or electrolytic plating on a metal film formed by PVD.

The semiconductor device 100 is manufactured by the processes described above. The plurality of semiconductor devices 100 are manufactured in a matrix in one n-type wafer, thus the n-type wafer is divided into each the semiconductor device 100 by laser dicing or blade dicing, and the semiconductor device 100 is completed.

### Embodiment 2

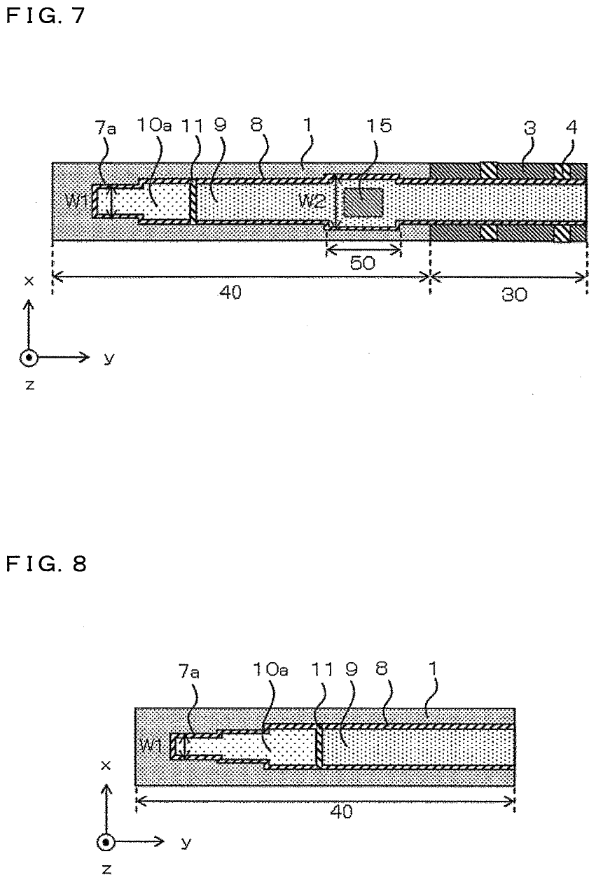

A semiconductor device according to an embodiment 2 is described using FIGS. 6 and 7. FIGS. 6 and 7 illustrate plan views in the outer surrounding part of the trench 7 in the manner similar to FIGS. 4 and 5. Herein, as illustrated in FIG. 6, the width of the trench end portion 7a in the trench 7 is a first width W1. A trench width of a region with the largest trench width in the trench 7 is a second width W2. In the semiconductor device according to the embodiment 2, the trench width is formed to be smallest in the trench end portion 7a in the trench 7 in the manner similar to the embodiment 1. Furthermore, the trench width of the trench end portion 7a has a feature that it is smaller than a width of a region with the largest trench width in the trench 7. That is to say, the trench 7 is formed so that the trench width is W1<W2, and the trench width gets gradually smaller toward a tip end of the trench end portion 7a so that the trench width is changes from W2 to W1. In the embodiment 2, the region with the largest trench width is a region corresponding to a part of the upper electrode 9 in the outer surrounding region in the trench 7.

According to the above configuration, the mesa width is enlarged in the region with the small trench width, thus the discharge path of the holes can be enlarged. Discharge of the holes is promoted, thus increase of the hole density in the region with the largest trench width where the holes are hardly discharged is suppressed, and avalanche withstand voltage can be improved.

As illustrated in FIG. 7, it is considered that a lifting region 50 electrically connecting the upper electrode 9 to the gate electrode 15 includes the region with the largest trench width, and the trench width in the lifting region 50 is larger than that corresponding to the upper electrode 9 located in the active region 30 in the trench 7. The reason is that the trench width of the lifting region 50 increases by an area where a contact hole for electrically connecting the upper electrode 9 to the gate electrode 15 is disposed. The mesa width in the lifting region 50 decreases, thus the hole density increases and the avalanche withstand voltage is easily reduced.

In this case, as illustrated in FIG. 7, the trench width of the lifting region 50 with the largest trench width is W2, the trench width of the trench end portion 7a as the region with the smallest trench width is W1, and W1<W2 is satisfied. Furthermore, the trench width is gradually reduced toward the trench end portion 7a so that the trench width is changed from W2 to W1.

According to the above configuration, the mesa width is enlarged in the region other than the lifting region 50, thus the discharge path of the holes can be enlarged. Discharge of the holes is promoted, thus increase of the hole density in the lifting region 50 where the holes are hardly discharged is suppressed, and the avalanche withstand voltage can be improved.

As described above, in the semiconductor device according to the embodiment 2, increase of the hole density can be suppressed, and the avalanche withstand voltage can be improved even in a case where the region with the largest trench width where the holes are hardly discharged is located in addition to the effect similar to that in the embodiment 1.

### Embodiment 3

A semiconductor device according to an embodiment 3 is described using FIGS. 8 to 10. FIGS. 8 to 10 illustrate plan views in the outer surrounding part of the trench 7 in the manner similar to FIGS. 4 and 5. Herein, the semiconductor device according to the embodiment 3 is formed so that the width of the trench end portion 7a is W1 and the trench width in the trench end portion 7a is the smallest width W1 in the manner similar to the embodiment 1. Furthermore, the semiconductor device according to the embodiment 3 has a feature that the trench width gradually gets smaller toward the tip end of the trench end portion 7a.

As illustrated in FIG. 8, in the semiconductor device according to the embodiment 3, the trench width is reduced by a level difference in two or more stages, and is the smallest W1 in the trench end portion 7a. The trench width is reduced in stages, thus disbalance of the hole density in the trench 7 can be reduced, and an electrical field concentration can be reduced, and the avalanche withstand voltage can be further improved.

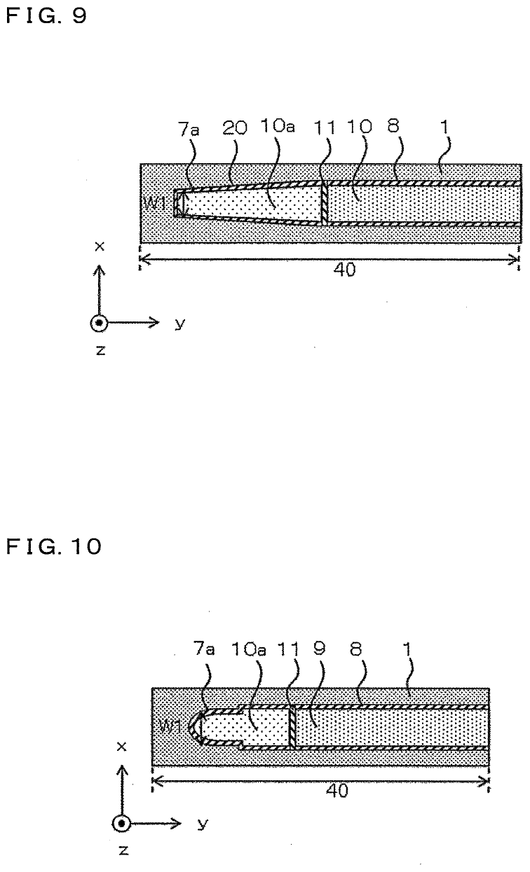

As illustrated in FIG. 9, a taper 20 may be provided to the trench end portion 7a. The taper 20 is provided, thus the width of the trench 7 can be gradually reduced toward the tip end of the trench 7. That is to say, the width of the trench 7 can be the smallest W1 in the trench end portion 7a. According to the above configuration, disbalance of the hole density in the trench 7 can be reduced, and the electrical field concentration can be reduced, thus the avalanche withstand voltage can be further improved. The taper is provided only to the trench end portion 7a in FIG. 9, but may also be provided to a region corresponding to the upper electrode 9 in the trench 7.

As illustrated in FIG. 10, also applicable is a configuration that the tip end of the trench end portion 7a is formed into a round shape. When the tip end of the trench end portion 7a has an angular shape, the electrical field is easily concentrated on the trench end portion 7a. A corner of the trench end portion 7a is eliminated and formed into the round shape, thus the width of the trench 7 can be gradually reduced toward the tip end of the trench 7. That is to say, the width of the trench 7 can be the smallest W1 in the trench end portion 7a. According to the above configuration, disbalance of the hole density in the trench 7 can be reduced, and the electrical field concentration can be reduced, thus the avalanche withstand voltage can be further improved.

As described above, in the semiconductor device according to the embodiment 3, the disbalance of the hole density can be suppressed, and the electrical field concentration can be reduced, thus the avalanche withstand voltage can be further improved in addition to the effect similar to that in the embodiment 1.

### Embodiment 4

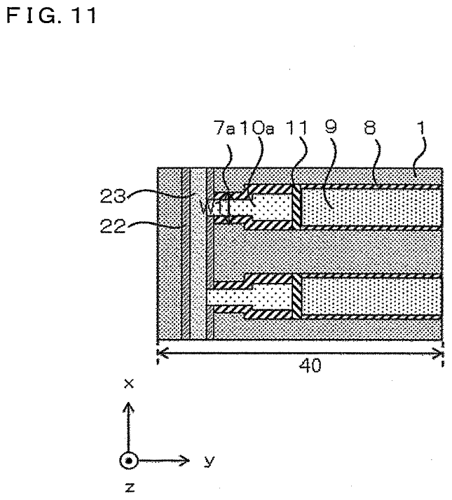

A semiconductor device according to an embodiment 4 is described using FIG. 11. FIG. 11 illustrates a plan view in the outer surrounding part of the trench 7 in the manner similar to FIGS. 4 and 5. The semiconductor device according to the embodiment 4 is formed so that the width of the trench end portion 7a is the first width W1 and the trench width in the trench end portion 7a is the smallest width W1 in the manner similar to the embodiment 1. The semiconductor device according to the embodiment 4 further has a feature that each of the extension parts 10a is bonded by a cross trench 21 extending in an X direction as a direction intersecting with the extension direction of the trench 7, and the lower electrodes 10 adjacent to each other are connected to each other.

An inner wall surface of the cross trench 21 is covered by an insulating film. The insulating film may be formed of a single film similar to the upper insulating film 8a and the lower insulating film 8b, but is a cross insulating film 22 in the embodiment 4. A cross electrode 23 is provided in the cross trench 21 via the cross insulating film 22. In the cross electrode 23, the extension part 10a of the lower electrode 10 may be formed to extend in an X direction as a direction intersecting with the extension direction of the trench 7. The cross electrode 23 is electrically connected to the emitter electrode 13. Herein, when the cross trench 21 is formed as with a case of the embodiment 4, the portion of the cross trench 21 is not included in “the trench end portion 7a”. According to the configuration described above, the avalanche withstand voltage in the trench end portion 7a can be further improved. This reason is described hereinafter.

The trench end portion 7a is a portion where the electrical field is easily concentrated. Particularly, in the turn-off switching operation, the holes are pulled to the lower electrode 10 having emitter potential more easily than the upper electrode 9 having gate potential. That is to say, the holes are easily pulled to the trench end portion 7a where the extension part 10a is disposed in the lower electrode 10. Accordingly, the electrical field in the trench end portion 7a increases, and dynamic avalanche occurs, thus such a configuration may cause deterioration of characteristics of the semiconductor device.

Herein, the trench end portions 7a adjacent to each other are connected by the cross trench 21 as with the case of the embodiment 4, thus protrusion of each of the trench end portions 7a is prevented, and the electrical field can be reduced. Furthermore, the trench width is the smallest W1 in the trench end portion 7a in the manner similar to the embodiment 1, thus the effect similar to the embodiment 1 can be acquired.

As described above, in the semiconductor device according to the embodiment 4, the hole density can be suppressed and occurrence of avalanche can be suppressed in the manner similar to the embodiment 1. Furthermore, the electrical field in the trench end portion 7a can be further reduced, and the avalanche withstand voltage can be further improved.

The configurations described in the above embodiments describe examples of the contents of the present disclosure, thus can be combined with the other known technique. A part of the configuration can be omitted or changed without departing from the scope of the present disclosure.

Described in the above embodiments is the example of the IGBT having the split gate trench structure that the first conductivity type is the n type and the second conductivity type is the p type. However, it is only the example, thus also applicable is an IGBT having a split gate trench structure of a p-channel type in which a conductivity type of each constituent element is reversed with respect to an n-channel type, for example. Furthermore, the invention of the present application can also be applied to a MOSFET having a similar structure. In the case of the MOSFET, electrons and holes are generated in occurrence of the avalanche. When the invention of the present application is applied to the MOSFET, discharge of the generated holes is promoted, and deterioration of characteristics of the semiconductor device can be suppressed.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device including an active region in which a semiconductor switching element is provided and an outer surrounding region in which a gate electrode is provided on an outer side of the active region, wherein
the semiconductor switching element includes:
a first conductivity type drift layer;
a second conductivity type base layer provided on a side of an upper surface of the first conductivity type drift layer;
a first conductivity type source layer provided on a side of an upper surface of the second conductivity type base layer;
a second conductivity type collector layer provided on a side of a lower surface of the first conductivity type drift layer;
an emitter electrode electrically connected to the first conductivity type source layer, and
a collector electrode electrically connected to the second conductivity type collector layer, wherein
a range from an upper surface of the first conductivity type source layer to a lower surface of the second conductivity type collector layer is defined as a semiconductor substrate,
the semiconductor device further includes:
a plurality of trenches passing through the semiconductor substrate from an upper surface of the semiconductor substrate to reach the first conductivity type drift layer in a depth direction, and extending from the active region toward the outer surrounding region; and
an interlayer insulating film covering each of the plurality of trenches, wherein
each of the plurality of trenches has a two-stage structure that a lower electrode, a boundary insulating film, and an upper electrode are stacked in sequence via an insulating film inside each of the plurality of trenches,
the lower electrode is electrically connected to the emitter electrode,
the upper electrode is electrically connected to the gate electrode,
an extension part of the lower electrode extending to an outer side of the upper electrode further extends to the upper surface of the semiconductor substrate to cover an end portion of the upper electrode, in an outer surrounding part of each of the plurality of trenches located in the outer surrounding region in an extension direction, and
a width of each of the plurality of trenches is smallest in the end portion of each of the plurality of trenches.

2. The semiconductor device according to claim 1, wherein
the width of each of the plurality of trenches is smallest in a region corresponding to the extension part of the lower electrode and a part of the upper electrode in the plurality of trenches.

3. The semiconductor device according to claim 1, wherein
the width of each of the plurality of trenches is gradually reduced toward a tip end of the trench end portion.

4. The semiconductor device according to claim 3, wherein
the width of each of the plurality of trenches is reduced in stages.

5. The semiconductor device according to claim 3, wherein
a taper is provided to the trench end portion.

6. The semiconductor device according to claim 3, wherein
the tip end of the trench end portion is formed into a round shape.

7. The semiconductor device according to claim 1, wherein
the width of each of the plurality of trenches is gradually reduced toward the tip end of the trench end portion from a width of a region with a largest trench width.

8. The semiconductor device according to claim 7, wherein
the region with the largest trench width is included in a lifting region connecting the upper electrode to the gate electrode.

9. The semiconductor device according to claim 1, wherein
a cross trench is further provided to connect an area of the tip end of the trench end portion and the tip end of the trench end portion adjacent to each other in the plurality of trenches,
a cross electrode is provided inside the cross trench via an insulating film, and
the cross electrode is electrically connected to the emitter electrode.
